(19) United States
(12) Patent Application Publication
(10) Pub. No.: US 2016/0340468 A1
(43) Pub. Date: Nov. 24, 2016

(54) HALOGEN FREE EPOXY FORMULATIONS WITH LOW DIELECTRIC CONSTANT

(71) Applicant: Blue Cube IP LLC, Midland, MI (US)

(72) Inventors: Jaclyn MURPHY, Rosharon, TX (US); Joey W. STORER, Midland, MI (US)

(21) Appl. No.: 15/107,131

(22) PCT Filed: Dec. 17, 2014
(86) PCT No.: PCT/US2014/070947

§ 371 Date: Jun. 22, 2016

Related U.S. Application Data
(60) Provisional application No. 61/921,550, filed on Dec. 30, 2013.

(51) Int. Cl. C08G 59/40; H05K 1/03; C08L 63/04; C08J 5/24; C08G 59/42; C08G 59/08

(52) U.S. Cl. CPC C08G 59/4071; C08G 59/4261; C08G 59/08; C08L 63/04; C08J 5/24; H05K 1/0326; C08J 2363/04; C08L 2203/20; C08L 2205/03

(57) ABSTRACT

A formulation comprising a) an epoxy component comprising an epoxy novolac and optionally an epoxy compound selected from the group consisting of an oxazolidone-modified epoxy, a phosphorus-containing epoxy, and combinations thereof; and b) a hardener component comprising i) a phosphorus-containing compound selected from the group consisting of an oligomeric compound comprising a phosphorus composition which is the reaction product of an etherified resole with 9,10-dihydro-9-oxa-10-phosphaphenanthrene-10-oxide, a phosphorus-containing filler and combinations thereof and ii) a polymeric anhydride compound selected from the group consisting of a styrene-maleic anhydride compound having a ratio of styrene to maleic anhydride of from 5:1 to 10:1, a modified styrene-maleic anhydride maleimide terpolymer, and combinations thereof, is disclosed.

### FIELD OF THE INVENTION

The present invention is related to epoxy resin compositions. More particularly, the present invention is related to halogen-free or substantially halogen-free formulations.

### INTRODUCTION

The demand for halogen-free material in the electronics market is forecasted to increase in the upcoming years. There are three reasons for this forecast. The first reason is the unfavorable public perception of halogenated materials. Several organizations actively campaign against halogenated materials. The second reason is the perceived upcoming regulations on brominated systems. Many manufacturers believe that governments will start regulating brominated flame retardants in laminate systems and companies are trying to outpace possible new regulations. The third reason is that compared to brominated systems, phosphorous-based systems tend to have higher thermal stabilities.

One new application area for halogen-free formulations is mobile devices, particularly smartphones and tablets. Recent market studies show that 22% of mobile phone sales in 2013 were smartphones and predicted that smartphones will be approximately 75% of phones sales by 2017. In 2012, tablets generated $54 billion in revenue and it is forecasted that the tablet market will generate $111 billion in 2017. The fact that smartphones and tablets are consumer products and are at the mercy of public perception; the use of halogen-free materials is expected to be adopted by large market producers. Given the bullish forecasts for these market segments, developing high performance, halogen-free products to sell into these market spaces is necessary.

Importantly, the halogen free market place is also requiring improvements in the dielectric constant. The dielectric constant requirements are trending lower (Dk<4.0) along with brominated products and for the same reasons. The reasons include 1) increasing battery sizes in mobile devices require smaller printed circuit boards and lowering the dielectric constant supports higher circuit density associated with smaller circuit board format; 2) the circuit boards in mobile devices are also getting thinner and a lower dielectric constant reduces the degrading effects of capacitive coupling between the ground plane and the input circuitry; 3) a lower dielectric constant is often associated with lower (improved) dissipation factor (Df) Improved dissipation factors are already becoming requirements for mobile consumer products. The lowering of both the Dk and the Df often causes the copper peel strength to be degraded. Therefore, halogen-free materials which have lower Dk and Df, but also with favorable copper peel strengths, are desirable.

### SUMMARY

In one broad embodiment of the present invention, there is disclosed a formulation comprising, consisting of, or consisting essentially of: a) an epoxy component comprising an epoxy novolac and optionally an oxazolidone-modified epoxy; and b) a hardener component comprising i) a phosphorus-containing compound selected from the group consisting of an oligomeric compound comprising a phosphorus composition which is the reaction product of an etherified resole with 9,10-dihydro-9-oxa-10-phosphaphenanthrene-10-oxide, a phosphorus-containing epoxy compound, a phosphorus-containing filler and combinations thereof and ii) a polymeric anhydride compound selected from the group consisting of a styrene-maleic anhydride compound having a ratio of styrene to maleic anhydride of from 5:1 to 10:1, a modified styrene-maleic anhydride maleimide terpolymer, and combinations thereof. The formulation is either bromine-free or substantially bromine-free.

### DETAILED DESCRIPTION

The composition contains an epoxy component comprising an epoxy novolac, Examples suitable for the present invention include, but are not limited to Dow XZ-92747, eBPAN from Kolon, Inc. In various embodiments, epoxy bisphenol-A novolac (eBPAN) is used. In various other embodiments, D.E.N.® 438 is used. Other examples of epoxy novolacs include, but are not limited to D.E.N.® 425, D.E.N.® 431 D.E.N.® 439, and D.E.N.® 440.

In various embodiments, the composition can optionally contain an oxazolidone-modified epoxy. An oxazolidone-modified epoxy is formed when an epoxide is reacted with an isocyanate. One example of an oxazolidone-modified epoxy is Dow XZ-97103. In an embodiment, a suitable oxazolidone-modified epoxy is depicted in Formula I, below.

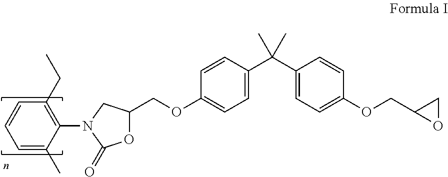

In Formula I, n is an integer from 2 to 20.

Generally, the epoxy component is present in the formulation in an amount in the range of from 15 weight percent to 60 weight percent, based on solids. The epoxy component is present in an amount in the range of from 20 weight percent to 50 weight percent in another embodiment, and is present in an amount in the range of from 30 weight percent to 40 weight percent in yet another embodiment, based on solids.

Various embodiments of this invention contain epoxy bisphenol-A novolac as the sole epoxy-containing component. Other embodiments of this invention contain an oxazolidinone-modified epoxy component as the sole epoxy-containing component. Still other embodiments contain a mixture of bisphenol-A novolac epoxy resins and oxazolidinone-modified epoxy resins in ratios ranging from 100% bisphenol A novolac epoxy resins to 100% oxazolidinone-modified epoxy resins and intermediate ratios of eBPAN to oxazolidinone-modified resins. Optionally, embodiments of this invention can contain a third epoxy resin, such as another novolac epoxy resin or a phosphorus epoxy resin. Examples of phosphorus-containing epoxy compounds include, but are not limited to 10-(2,5-Dihydroxyphenyl)-10-H-9-Oxa-10-Phosphaphenanthrene-10-oxide (DOPO-HQ) modified epoxy resin, and 10-(2,9-DihydroxyNaphthyl)-10-H-9-Oxa-10-Phosphaphenanthrene-10-oxide (DOPO-NQ), and Prologic™ BF140, available from the Dow Chemical Company. Combinations of phosphorus-containing compounds can also be used. The third epoxy resin can be present in an amount ranging from 0 weight percent to 50 weight percent, from 5 weight percent to 45 weight percent in other embodiments, and from 10 weight percent to 30 percent in yet other embodiments.

The hardener component generally comprises a mixture of (i) a phosphorus containing compound and (ii) an anhydride hardener. The anhydride hardener is a styrene maleic anhydride copolymer in an embodiment, or a modified anhydride terpolymer in another embodiment.

In various embodiments, the hardener component of the formulation comprises a phosphorus-containing compound and a styrene-maleic anhydride compound.

In an embodiment, the phosphorus-containing compound is an oligomeric composition comprising a phosphorus-containing compound which is the reaction product of an etherified resole with 9,10-dihydro-9-oxa-10-phosphaphenanthrene-10-oxide ('H-DOP'). This reaction product, referred to hereinafter as ‘DOP-BN,’ is depicted in Formula II, below.

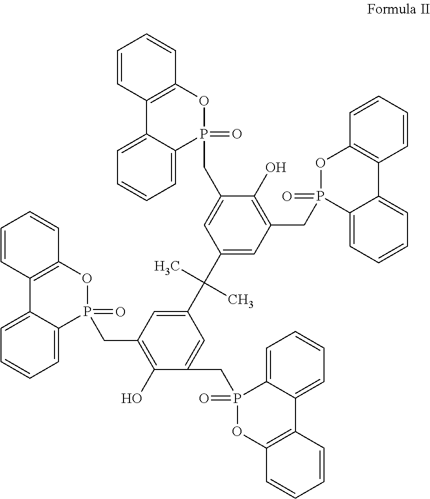 [SMILES: CC(C)(c1cc(CP2(=O)Oc3ccccc3-c3ccccc32)c(O)c(CP2(=O)Oc3ccccc3-c3ccccc32)c1)c1cc(CP2(=O)Oc3ccccc3-c3ccccc32)c(O)c(CP2(=O)Oc3ccccc3-c3ccccc32)c1]

Further information about DOP-BN and its preparation can be found in U.S. Pat. No. 8,124,716.

The phosphorus-containing compound is generally present in the formulation in the range of from 15 weight percent to 50 weight percent, based on the total weight of the formulation. The phosphorus-containing compound is present in an amount in the range of from 25 weight percent to 35 weight percent in another embodiment, based the total weight of the formulation.

In various embodiments, phosphorus is present in the range of from 2 weight percent to 8 weight percent, and is present in the range of from 3 weight percent to 5 weight percent in various other embodiments, based on the total weight of the formulation.

The hardener component also contains a polymeric anhydride hardener. Generally, the polymeric anhydride is selected from the group consisting of a maleic-anhydride containing compound, a maleic anhydride-containing vinyl compound, and combinations thereof. In various embodiments, the polymeric anhydride is styrene-maleic anhydride. In various other embodiments, the polymeric anhydride is a modified styrene-maleic anhydride maleimide terpolymer.

In various embodiments, the styrene-maleic anhydride has a ratio of styrene to maleic anhydride of from 5:1 to 10:1. Commercial examples of styrene-maleic anhydride compounds include, but are not limited to SMA® EF-60 and SMA® EF-80, both of which are available from Cray Valley or from Polyscope, for example, C500, C600, C700 series co-polymers.

In various embodiments, styrene and maleic anhydride copolymers can be reacted with aromatic amine compounds such as aniline to form a terpolymer. The process for modifying the styrene and maleic anhydride copolymer can include imidization. Further information about modified styrene and maleic anhydride copolymers and their preparation can be found in International Publication No. WO 2013/000151 A1. For the various embodiments, the styrene and maleic anhydride copolymers have a styrene to maleic anhydride molar ratio of 1:1 to 10:1; for example; the copolymer can have a molar ratio of styrene to maleic anhydride of 5:1 to 10:1 in an embodiment and a molar ratio of from 6:1 to 8:1 in another embodiment.

The polymeric anhydride hardener is generally present in the formulation in the range of from 0 weight percent to 50 weight percent, based on the total weight of the formulation. The polymeric anhydride hardener is present in an amount in the range of from 25 weight percent to 50 weight percent in another embodiment, based on the total weight of the formulation.

Optionally, catalysts can be added to the curable composition. Examples of catalysts that can be used include, but are not limited to 2-methyl imidazole (2MI), 2-phenyl imidazole (2PI), 2-ethyl-4-methyl imidazole (2E4MI), 1-benzyl-2-phenylimidazole (1B2PZ), dicyandiamide (DICY), urea, boric acid, triphenylphosphine (TPP), tetraphenylphosphonium-tetraphenylborate (TPP-k), zinc alkyloate, and mixtures thereof.

The catalyst can be present in various amounts depending on the particular embodiment. The range of the amount catalyst present can range from 0.02 parts per hundred to 0.15 parts per hundred depending on the embodiment and the desired gel time of the formulation.

In one or more embodiments, the curable composition can also include inorganic fillers. Examples of fillers include but are not limited to silica, aluminum trihydrate (ATH), magnesium hydroxide, carbon black, and combinations thereof.

In one or more embodiments, the curable composition can contain a solvent. Solvents can be used to solubilize the epoxy and hardener component or to adjust the viscosity of the final varnish. Examples of solvents that can be used include, but are not limited to methanol, acetone, n-butanol, methyl ethyl ketone (MEK), cyclohexanone, benzene, toluene, xylene, dimethylformamide (DMF), ethyl alcohol (EtOH), propylene glycol methyl ether (PM), propylene glycol methyl ether acetate (DOWANOL™ PMA) and mixtures thereof.

Toughening agents, such as core shell rubbers, can also optionally be used in the formulation. A core shell rubber is a polymer comprising a rubber particle core formed by a polymer comprising an elastomeric or rubbery polymer as a main ingredient and a shell layer formed by a polymer graft polymerized on the core. The shell layer partially or entirely covers the surface of the rubber particle core by graft polymerizing a monomer to the core. Generally the rubber particle core is constituted from acrylic or methacrylic acid ester monomers or diene (conjugated diene) monomers or vinyl monomers or siloxane type monomers and combinations thereof. The toughening agent may be selected from commercially available products; for example, Paraloid EXL 2650A, EXL 2655, EXL2691 A, each available from The Dow Chemical Company, or Kane Ace® MX series from Kaneka Corporation, such as MX 120, MX 125, MX 130, MX 136, MX 551, or METABLEN SX-006 available from Mitsubishi Rayon.

Adhesion promoters can also optionally be used in the formulation. Examples of adhesion promoters include, but not limited to, silanes, titanates, zirconates and various compounds or polymers containing heteroatoms such as nitrogen, oxygen or sulfur. Embodiments can also contain mixtures of adhesion promoters.

Depending on the type of adhesion promoter used, these promoters can be present in ranges from 0.05 weight percent to 5.0 weight percent, based on the total weight of the formulation.

The composition can be produced by any suitable process known to those skilled in the art. In an embodiment, solutions of the epoxy component, phosphorus-containing compound, and polymeric anhydride are mixed together. Any other desired component, such as the optional components described above, are then added to the mixture.

Embodiments of the present disclosure provide prepregs that includes a reinforcement component and the curable composition, as discussed herein. The prepreg can be obtained by a process that includes impregnating a matrix component into the reinforcement component. The matrix component surrounds and/or supports the reinforcement component. The disclosed curable compositions can be used for the matrix component. The matrix component and the reinforcement component of the prepreg provide a synergism. This synergism provides that the prepregs and/or products obtained by curing the prepregs have mechanical and/or physical properties that are unattainable with only the individual components. The prepregs can be used to make electrical laminates for printed circuit boards.

The reinforcement component can be a fiber. Examples of fibers include, but are not limited to, glass, aramid, carbon, polyester, polyethylene, quartz, metal, ceramic, biomass, and combinations thereof. The fibers can be coated. An example of a fiber coating includes, but is not limited to, boron.

Examples of glass fibers include, but are not limited to, A-glass fibers, E-glass fibers, C-glass fibers, R-glass fibers, S-glass fibers, T-glass fibers, and combinations thereof. Aramids are organic polymers, examples of which include, but are not limited to, Kevlar®, Twaron®, and combinations thereof. Examples of carbon fibers include, but are not limited to, those fibers formed from polyacrylonitrile, pitch, rayon, cellulose, and combinations thereof. Examples of metal fibers include, but are not limited to, stainless steel, chromium, nickel, platinum, titanium, copper, aluminum, beryllium, tungsten, and combinations thereof. Examples of ceramic fibers include, but are not limited to, those fibers formed from aluminum oxide, silicon dioxide, zirconium dioxide, silicon nitride, silicon carbide, boron carbide, boron nitride, silicon boride, and combinations thereof. Examples of biomass fibers include, but are not limited to, those fibers formed from wood, non-wood, and combinations thereof.

The reinforcement component can be a fabric. The fabric can be formed from the fiber, as discussed herein. Examples of fabrics include, but are not limited to, stitched fabrics, woven fabrics, and combinations thereof. The fabric can be unidirectional, multiaxial, and combinations thereof. The reinforcement component can be a combination of the fiber and the fabric.

The prepreg is obtainable by impregnating the matrix component into the reinforcement component Impregnating the matrix component into the reinforcement component may be accomplished by a variety of processes. The prepreg can be formed by contacting the reinforcement component and the matrix component via rolling, dipping, spraying, or other such procedures. After the prepreg reinforcement component has been contacted with the prepreg matrix component, the solvent can be removed via volatilization. While and/or after the solvent is volatilized the prepreg matrix component can be cured, e.g. partially cured. This volatilization of the solvent and/or the partial curing can be referred to as B-staging. The B-staged product can be referred to as the prepreg.

For some applications, B-staging can occur via an exposure to a temperature of 60° C. to 250° C.; for example B-staging can occur via an exposure to a temperature from 65° C. to 240° C., or 70° C. to 230° C. For some applications, B-staging can occur for a period of time of 1 minute (min) to 60 min; for example B-staging can occur for a period of time from, 2 min to 50 min, or 5 min to 40 min. However, for some applications the B-staging can occur at another temperature and/or another period of time.

One or more of the prepregs may be cured (e.g. more fully cured) to obtain a cured product. The prepregs can be layered and/or formed into a shape before being cured further. For some applications (e.g. when an electrical laminate is being produced) layers of the prepreg can be alternated with layers of a conductive material. An example of the conductive material includes, but is not limited to, copper foil. The prepreg layers can then be exposed to conditions so that the matrix component becomes more fully cured.

One example of a process for obtaining the more fully cured product is pressing. One or more prepregs may be placed into a press where it subjected to a curing force for a predetermined curing time interval to obtain the more fully cured product. The press has a curing temperature in the curing temperature ranges stated above. For one or more embodiments, the press has a curing temperature that is ramped from a lower curing temperature to a higher curing temperature over a ramp time interval.

During the pressing, the one or more prepregs can be subjected to a curing force via the press. The curing force may have a value that is 10 kilopascals (kPa) to 350 kPa; for example the curing force may have a value that is 20 kPa to 300 kPa, or 30 kPa to 275 kPa. The predetermined curing time interval may have a value that is 5 s to 500 s; for example the predetermined curing time interval may have a value that is 25 s to 540 s, or 45 s to 520 s. For other processes for obtaining the cured product other curing temperatures, curing force values, and/or predetermined curing time intervals are possible. Additionally, the process may be repeated to further cure the prepreg and obtain the cured product.

The prepregs can be used to make composites, electrical laminates, and coatings. Printed circuit boards prepared from the electrical laminates can be used for a variety of applications. In an embodiment, the printed circuit boards are used in smartphones and tablets. In various embodiments, the electrical laminates have a copper peel strength in the range of from 4 lb/in to 12 lb/in.

### EXAMPLES

The raw materials used are shown below.
KEB-3165, an epoxy bisphenol-A novolac, from Kolon
Styrene maleic anhydride copolymer SMA® EF-60, from Cray Valley
XZ-92741 (DOP-BN), from The Dow Chemical Company
XZ-97103, an oxazolidone-modified epoxy from The Dow Chemical Company
Fortegra™ toughener from The Dow Chemical Company
XZ-97102, a phosphorous-containing phenolic hardener from the Dow Chemical Company
Copper foils from Oak Mitsui

### Example 1

The components of the halogen free low Dk formulation were mixed on a shaker at room temperature until a solution was formed. KEB-3165 (33 weight percent), XZ 92741 (31 weight percent), SMA® EF-60 (30 weight percent), and XZ-97102 (5 weight percent) were combined together to prepare a varnish. A 12″ by 12″ sheet of 1080 CS-718 woven glass was stapled to a wooden frame. Twenty to twenty-five mL of varnish was poured onto the glass sheet and was spread using a paint brush. The sheet was then placed into a 177° C. oven and was partially advanced. The advancement time was determined by testing the prepreg powered reactivity. A prepreg reactivity of 80 seconds was targeted and each sheet of prepreg had a resin content of approximately 75%. Eight sheets of prepreg were then stacked and cured in a Tetrahedron press to produce a laminate board. The resulting laminate board was 69% resin (determined by TGA). The specific press conditions, laminate properties and testing conditions are given in Tables 1 and 2, below.

TABLE 1
Press Conditions

1. 9° F./min to 266° F. Hold for 10 s, F = 10 psi
2. 9° F./min to 374° F. Hold for 2 h, F = 200 psi
3. 10° F./min to 95° F. F = 200 psi

TABLE 2
Laminate Properties (8-ply, 1080 glass, 69% resin)

| | |
|---|---|
| Tg (° C., DSC), IPC-TM-650, 2.4.24C[4] | 166 |
| Decomposition Temp. (° C., at 5% wt. loss by TGA), | 379 |
| IPC-TM-650, 2.4.24.6 | |
| Copper Peel Strength (lb/in), IPC TM-650 2.4.8.2 | 4.5 |
| Dk (7 GHz, IPC-TM-650 2.5.5.13, Split cylinder) | 3.42 |

### Comparative Example A

The components of the halogen free low Dk formulation were mixed on a shaker at room temperature until a solution was formed. This specific formulation contained KEB-3165 (54 weight percent), XZ 92741 (37 weight percent) and and XZ-97012 (6 weight percent). A 12″ by 12″ sheet of 1080 CS-718 woven glass was stapled to a wooden frame. Twenty to twenty-five mL of varnish was poured onto the glass sheet and was spread using a paint brush. The sheet was then placed into a 177° C. oven and was partially advanced. The advancement time was determined by testing the prepreg powered reactivity. A prepreg reactivity of 80 seconds was targeted and each sheet of prepreg had a resin content of approximately 75%. Eight sheets of prepreg were then stacked and cured in a Tetrahedron press to produce a laminate board. The resulting laminate board was 50% resin (determined by TGA). The specific press conditions, laminate properties and testing conditions are given in Tables 3 and 4 below.

TABLE 3
Press Conditions

1. 9° F./min to 266° F. Hold for 10 s, F = 10 psi
2. 9° F./min to 394° F. Hold for 2 h, F = 200 psi
3. 10° F./min to 95° F. F = 200 psi

TABLE 4
Laminate Properties (6-ply, 2116 glass, 50% resin)

| | |
|---|---|
| Tg (° C., DSC) IPC-TM-650, 2.4.24C[4] | 192 |
| Decomposition Temp. (° C., at 5% wt. loss by TGA) | 377 |
| IPC-TM-650, 2.4.24.6 | |
| Copper Peel Strength (lb/in), IPC TM-650 2.4.8.2 | >6 lb/in |
| Dk (7 GHz, IPC-TM-650 2.5.5.13, Split cylinder) | 4.03 |

### Comparative Example B

The components of the halogen free low Dk formulation were mixed on a shaker at room temperature until a solution was formed. This specific formulation contained KEB-3165 (25 weight percent), XZ 92741 (45 weight percent) and SMA® EF-60 (29 weight percent). A 12″ by 12″ sheet of 2116 CS-718 woven glass was stapled to a wooden frame. Twenty to twenty-five mL of varnish was poured onto the glass sheet and was spread using a paint brush. The sheet was then placed into a 177° C. oven and was partially advanced. The advancement time was determined by testing the prepreg powered reactivity. A prepreg reactivity of 80 seconds was targeted and each sheet of prepreg had a resin content of approximately 52%. Eight sheets of prepreg were then stacked and cured in a Tetrahedron press to produce a laminate board. The resulting laminate board was 69% resin (determined by TGA). The specific press conditions, laminate properties and testing conditions are given in Tables 5 and 6, below.

TABLE 5
Press Conditions

1. 9° F./min to 266° F. Hold for 3 min, F = 10 psi
2. 9° F./min to 374° F. Hold for 2 h, F = 150 psi
3. 10° F./min to 95° F. F = 150 psi

TABLE 6
Laminate Properties (6-ply, 2116 glass, 52% resin)

| | |
|---|---|
| Tg (° C., DSC) IPC-TM-650, 2.4.24C[4] | 166 |
| Decomposition Temp. (° C., at 5% wt. loss by TGA) | 381 |
| IPC-TM-650, 2.4.24.6 | |
| Copper Peel Strength (lb/in), IPC TM-650 2.4.8.2 | 2.4 |
| Dk (7 GHz, IPC-TM-650 2.5.5.13, Split cylinder) | 4.02 |

### Example 2

The following halogen free low Dk formulation was prepared by mixing the components together at room temperature using a shaker until a solution was formed. XZ 97103 (32 weight percent), XZ 92741 (39 weight percent), SMA® EF-60 (26 weight percent) and Fortegra 351 (3.7 weight percent) were combined together to prepare a varnish. A 12″ by 12″ sheet of 1080 CS-718 woven glass was stapled to a wooden frame. Twenty to twenty-five mL of varnish was poured onto the glass sheet and was spread using a paint brush. The sheet was then placed into a 177° C. oven and was partially advanced. The advancement time was determined by testing the prepreg powered reactivity. A prepreg reactivity of 80 seconds was targeted and each sheet of prepreg had a resin content of approximately 71%. Eight sheets of prepreg were then stacked and cured in a Tetrahedron press to produce a laminate board. The resulting laminate board was 69% resin (determined by TGA). The specific press conditions, laminate properties and testing conditions are given in Tables 7 and 8, below.

TABLE 7
Press Conditions

1. 9° F./min to 320° F. Hold for 1 min, F = 10 psi
2. 9° F./min to 374° F. Hold for 2 h, F = 150 psi
3. 10° F./min to 95° F. F = 150 psi

TABLE 8
Laminate Properties (8-ply, 1080 glass, 71% resin)

| | |
|---|---|
| Tg (° C., DSC) IPC-TM-650, 2.4.24C[4] | 156 |
| Decomposition Temp. (° C., at 5% wt. loss by TGA) | 375 |
| IPC-TM-650, 2.4.24.6 | |
| Copper Peel Strength (lb/in), IPC TM-650 2.4.8.2 | 5.6 |
| Dk (7 GHz, IPC-TM-650 2.5.5.13, Split cylinder) | 3.38 |

### Comparative Example C

The following halogen free low Dk formulation was prepared by mixing the components together at room temperature using a shaker until a solution was formed. XZ 97103 (33 weight percent), XZ 92741 (40 weight percent) and SMA® EF-60 (27 weight percent) were combined together to prepare a varnish. This varnish was used to impregnate glass cloth (2116, CS-718). A 12″ by 12″ sheet of 2116 CS-718 woven glass was stapled to a wooden frame. Twenty to twenty-five mL of varnish was poured onto the glass sheet and was spread using a paint brush. The sheet was then placed into a 177° C. oven and was partially advanced. The advancement time was determined by testing the prepreg powered reactivity. A prepreg reactivity of 80 seconds was targeted and each sheet of prepreg had a resin content of approximately 71%. Eight sheets of prepreg were then stacked and cured in a Tetrahedron press to produce a laminate board. The resulting laminate board was 45% resin (determined by TGA). The specific press conditions, laminate properties and testing conditions are given in Tables 9 and 10, below.

TABLE 9
Press conditions.
Press Conditions

1. 9° F./min to 266° F. Hold for 10 s, F = 10 psi
2. 9° F./min to 351° F. Hold for 2 h, F = 125 psi
3. 10° F./min to 95° F. F = 125 psi

TABLE 10
Laminate properties.
Laminate Properties (8-ply, 2116 glass, 45% resin)

| | |
|---|---|
| Tg (° C., DSC) IPC-TM-650, 2.4.24C[4] | 154 |
| Decomposition Temp. (° C., at 5% wt. loss by TGA) | 384 |
| IPC-TM-650, 2.4.24.6 | |
| Copper Peel Strength (lb/in), IPC TM-650 2.4.8.2 | 4.5 |
| Dk (7 GHz, IPC-TM-650 2.5.5.13, Split cylinder) | 3.95 |

### Results of Examples

In example 1, it is demonstrated that combination of eBPAN, XZ 92741, XZ 97102 and SMA provide a mid-Tg formulation with a low Dk value and an acceptable copper peel strength. In comparative example A, it is shown that a comparable formulation without SMA has a high Dk (>4), which demonstrates the utility of the hardener combination. Example 2 demonstrates the utility of the combination of an oxazolidinone-modified epoxy resin and the combination of hardeners described in the invention, both with and without a toughening agent (core shell rubber).

1. A formulation comprising:
a) an epoxy component comprising an epoxy novolac and optionally an epoxy compound selected from the group consisting of an oxazolidone-modified epoxy, a phosphorus-containing epoxy and combinations thereof; and
b) a hardener component comprising
i) a phosphorus-containing compound selected from the group consisting of an oligomeric compound comprising a phosphorus composition which is the reaction product of an etherified resole with 9,10-dihydro-9-oxa-10-phosphaphenanthrene-10-oxide, a phosphorus-containing filler and combinations thereof and
ii) a polymeric anhydride compound selected from the group consisting of a styrene-maleic anhydride compound having a ratio of styrene to maleic anhydride of from 5:1 to 10:1, a modified styrene-maleic anhydride maleimide terpolymer, and combinations thereof.

2. A formulation in accordance with claim 1 further comprising a core shell rubber having a functional group selected from the group consisting of carboxyl groups, hydroxyl groups, carbon-carbon double bonds, anhydride groups, amino groups, amide groups, and combinations thereof.

3. A formulation in accordance with claim 1 wherein the epoxy novolac is epoxy bisphenol-A novolac.

4. A formulation in accordance with claim 1 wherein the modified styrene-maleic anhydride maleimide terpolymer is formed by reacting styrene-maleic anhydride with aniline.

5. A formulation in accordance with claim 1 wherein the phosphorus-containing compound is DOP-BN.

6. A formulation in accordance with claim 1 wherein the oxazolidone-modified epoxy has a formula of 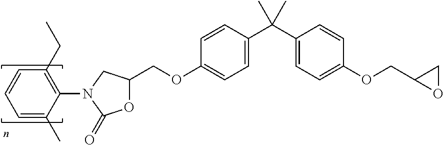
where n is an integer from 2 to 20.

7. A formulation in accordance with claim 1 further comprising a catalyst.

8. A formulation in accordance with claim 1 wherein the epoxy component is present in an amount in the range of from 15 weight percent to 60 weight percent, the phosphorus-containing compound is present in an amount in the range of from 15 weight percent to 50 weight percent, and the polymeric anhydride compound is present in an amount in the range of 0 weight percent to 50 weight percent, based on the total weight of the formulation.

9. A formulation in accordance with claim 1 having a total weight percent of atomic phosphorus in the range of from 2 weight percent to 8 weight percent.

10. A formulation in accordance with claim 7 wherein the catalyst is present in an amount in the range of from 0.02 parts per hundred to 0.15 parts per hundred.

11. A process for preparing the formulation of claim 1 comprising admixing a) an epoxy component comprising an epoxy novolac and optionally an epoxy compound selected from the group consisting of oxazolidone-modified epoxy, a phosphorus-containing epoxy, and combinations thereof; and b) a hardener component comprising i) a phosphorus-containing compound selected from the group consisting of a compound which is the reaction product of an etherified resole with 9,10-dihydro-9-oxa-10-phosphaphenanthrene-10-oxide (H-DOP), a phosphorus-containing filler and combinations thereof and ii) a polymeric anhydride compound selected from the group consisting of a styrene-maleic anhydride compound having a ratio of styrene to maleic anhydride of from 5:1 to 10:1, a modified styrene-maleic anhydride maleimide terpolymer, and combinations thereof to form the formulation.

12. A prepreg prepared from the formulation of claim 1.

13. An electrical laminate prepared from the formulation of claim 1.

14. An electrical laminate in accordance with claim 13 wherein the electrical laminate has a copper peel strength in the range of from 3 to 12 lb/in.

15. A printed circuit board prepared from the electrical laminate of claim 13.

16. A formulation in accordance with claim 3, wherein the modified styrene-maleic anhydride maleimide terpolymer is formed by reacting styrene-maleic anhydride with aniline.

17. A formulation in accordance with claim 16, wherein the phosphorus-containing compound is DOP-BN.

18. A formulation in accordance with claim 17, wherein the oxazolidone-modified epoxy has a formula of 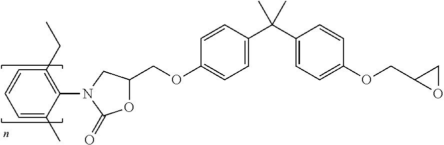
where n is an integer from 2 to 20.

19. A formulation in accordance with claim 18 further comprising a catalyst.
